(19) United States
(12) Patent Application Publication
(10) Pub. No.: US 2024/0222476 A1
(43) Pub. Date: Jul. 4, 2024

(54) WIDE BASED HIGH VOLTAGE BIPOLAR JUNCTION TRANSISTOR WITH BURIED COLLECTORS AS HYBRID IGBT BUILDING BLOCK

(71) Applicant: iPower Semiconductor, Gilroy, CA (US)

(72) Inventor: Hamza Yilmaz, Gilroy, CA (US)

(21) Appl. No.: 18/404,134

(22) Filed: Jan. 4, 2024

Related U.S. Application Data
(60) Provisional application No. 63/437,062, filed on Jan. 4, 2023.
(60) Provisional application No. 63/439,393, filed on Jan. 17, 2023.

(51) Int. Cl. H01L 29/732; H01L 29/06; H01L 29/08; H01L 29/10; H01L 29/423; H01L 29/739; H01L 29/78

(52) U.S. Cl. CPC H01L 29/732; H01L 29/0804; H01L 29/0821; H01L 29/1004; H01L 29/42304; H01L 29/7393; H01L 29/7811; H01L 29/0607

(57) ABSTRACT

A high voltage bipolar junction transistor (BJT) enables package integration with a MOSFET as a base driver for the BJT in the same package. The BJT may include a wide base to block the high voltage with a lightly doped wide-base region rather than in a lightly doped collector region. Collector regions of the BJT may be buried and additional floating collector regions may underly the buried collector regions. The package integration allows the MOSFET and the BJT to be fabricated using separately optimized semiconductor materials and processing while providing the operation of a power IGBT with higher performance.

### REFERENCE TO RELATED APPLICATIONS

This patent document is claims benefit of the earlier filing date of U.S. provisional Pat. App. No. 63/437,062, filed Jan. 4, 2023, and U.S. provisional Pat. App. No. 63/439,393, filed Jan. 17, 2023, both of which are hereby incorporated by reference in their entirety.

### BACKGROUND

Insulated-gate bipolar transistors (IGBTs) are integrated circuit devices that have primarily been used as electronic switches or power semiconductor devices. The internal structure of an IGBT generally includes four alternating (P-N-P-N) semiconductor layers that are controlled by a metal-oxide-semiconductor (MOS) gate structure. An IGBT generally has three accessible terminals, commonly referred to as the gate, emitter, and collector of the IGBT, and the gate voltage on an IGBT is normally used to control switching of a high voltage between the emitter and the collector. An IGBT ideally combines high efficiency and fast switching, but the semiconductor materials that may work best for the bipolar portion of an IGBT may not work best for the MOS gate structure.

### BRIEF DESCRIPTION OF THE DRAWINGS

FIG. 1A shows a cross-sectional view of a Wide Base and Buried Collector Bipolar Junction Transistor (WB-BC BJT) structure in accordance with an example of the present disclosure.

FIG. 1B shows a schematic of a MOSFET driven Wide Base and Buried Collector Bipolar Junction Transistor (WB-BC BJT) in accordance with an embodiment of the present disclosure.

FIG. 2 shows a cross-sectional view of a Wide Base, Buried and Floating Collectors Bipolar Junction Transistor (WB-BFC BJT) structure in accordance with an embodiment of the present disclosure.

FIG. 3A shows a cross-sectional view of an embodiment of high voltage edge termination for the WB-BC BJT structure of FIG. 1A.

FIG. 3B shows a cross-sectional view of an embodiment of high voltage edge termination with floating buried p rings for the WB-BC BJT structure in FIG. 2.

FIG. 4 shows a plan view of bonding pads of a WB-BC BJT device in accordance with an example of the present disclosure.

FIG. 5 shows a top view of a TO-2XX package before molding showing package integration of a MOSFET and a WB-BC BJT in accordance with an example of the present disclosure.

FIG. 6A shows a cross-sectional view of a WB-BC BJT structure with integrated Fast Recovery Diode (FRD) in accordance with an example of the present disclosure.

FIG. 6B shows the equivalent circuit of a package in accordance with an embodiment of the present disclosure that combines an FRD-WB-BC BJT chip and a MOSFET chip to provide an IGBT.

FIG. 7 shows a cross-sectional view of a WB-BC PNP BJT and an integrated FRD in accordance with an embodiment of the present disclosure.

The drawings illustrate examples for the purpose of explanation and are not of the invention itself. Use of the same reference symbols in different figures indicates similar or identical items.

### DETAILED DESCRIPTION

A high voltage Bipolar Junction Transistor (BJT) structure in accordance with an embodiment of the present disclosure may be constructed to enable package integration of a MOSFET as a base driver for the BJT. The package integration allows the MOSFET and the BJT to be fabricated using separately optimized semiconductor materials and processes, while the package provides the same connectivity as a conventional IGBT with higher performance than the conventional IGBT. The BJT structure, unlike a conventional BJT structure, may be a Wide Base Bipolar Junction Transistor (WB-BJT). In particular, the WB-BJT is constructed to block the high voltage with lightly doped wide-base region rather than in the lightly doped collector region of a conventional narrow based BJT such as may be used in a conventional bipolar junction transistor.

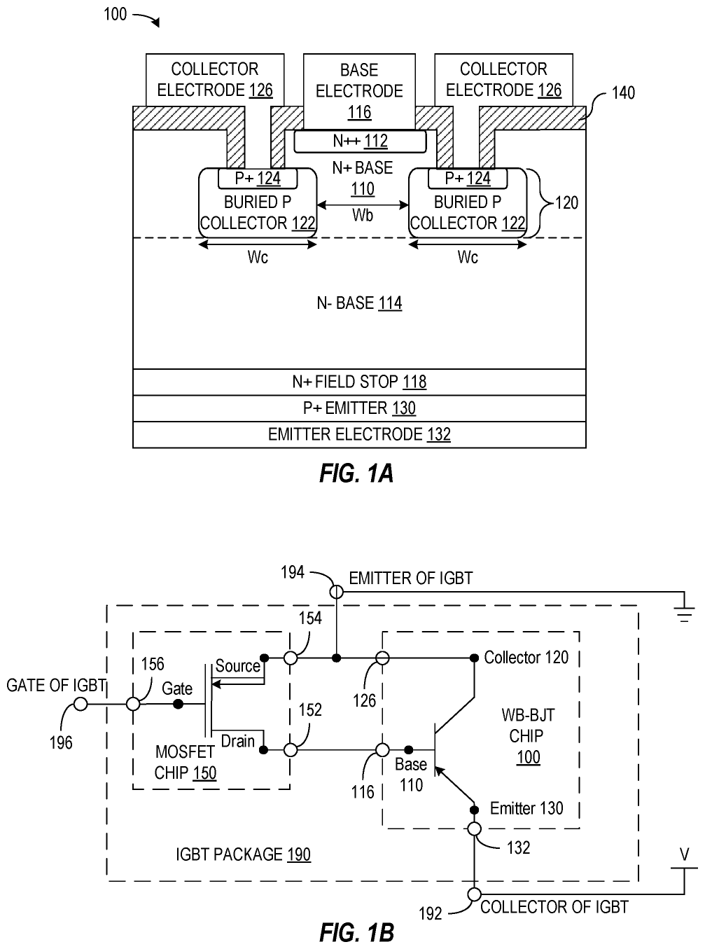

FIG. 1A shows the example cross-section of a WB-BJT 100 having an N-type base 110, P-type collector 120, and a P-type emitter 130. WB-BJT 100 may be a semiconductor device integrated on one chip or die, and in the example of FIG. 1A, WB-BJT 100 is a vertical PNP bipolar junction transistor. Alternatively, WB-BJTs using opposite conductivity types may employ a similar structure.

P-type collector 120 includes one or more buried collector (BC) structure or regions 122 that may, for example, be formed at the bottom of a trench that is later filled with insulation 140. A conductive via in the trench may electrically connect a buried P collector region to a metal collector electrode 126. Buried P collector regions 122 contain a P-type semiconductor material and may have a more highly doped portion 124 for an improved ohmic connection to collector electrode 126. P-type collector 120 may be adjacent to each region of N+ base 110 and may extend into a N− base layer 114 underlying the N+ base 110. FIG. 1A shows an example using buried collectors 122. Alternatively, a WB-BJT device could have surface P collectors but may require a larger die area to keep the P+ p collector and N+n− base regions far apart to prevent breakdown before the N− gap between collectors pinches off (i.e., is depleted completely).

The wide base structure of WB-BJT 100 in the example of FIG. 1A includes a metal base electrode 116, one or more N+ base regions 110, N-base layer 114, and a N+ field stop layer 118. N+ base 110 may include a more heavily doped portion 112 to improve an ohmic electrical connection to base electrode 116. N+ base 110 may be between or bounded by P buried collector regions 122 or the trench structures overlying the P buried collector regions 122. The N− base layer 114 may have a thickness and an N− doping concentration that is selected according to the desired breakdown voltage of WB BJT 100. N+ field stop layer 118 may be used to prevent depletion in the WB-BJT 100 from extending to P+ emitter 130.

N+ base 110 and P-type buried collector 122 may be patterned to provide at least one gap Wb, sometimes referred to herein as the base width Wb, under or adjacent to each region of N+ base 110. For example, each region of N+ base 110 may only be in electrical contact with N− base layer 114 through the gap or gaps Wb that the boundaries of buried collector 122 create. P-type collector 120 allows depletion of the gap Wb between the buried collector boundaries effectively before the N+ base 110 and the P collector 120 breakdown. The base width Wb corresponding to the gap between adjacent boundaries of buried collector 122 in the WB-BJT 100 may be about 3 to 40 microns depending on the N doping concentrations of N− base layer 114. This base width Wb may determine a pinch off voltage (Vpoff) in a portion of N− base layer 114 between boundaries of buried collector 122 adjacent to N+ base 110. Accordingly, this pinch off blocks the high voltage with lightly doped wide-base region, e.g., portions of N-base layer 114 in or near gap Wb, so that WB-BJT 100 does not require a lightly doped collector region such as may be used in a conventional narrow based BJT. The pinch off voltage Vpoff is important to the breakdown rating required for a MOSFET 150 (see FIG. 1B) and also to achieving a desired breakdown of a package integrated IGBT 190 that includes WB-BJT 100 and the MSOFET 150.

Regions of buried collector 122 of WB-BJT 100 may have a width Wc that is less than, equal to, or greater than base width Wb depending on the breakdown rating of WB-BJT 100. With such a structure, a thick N− base 114 and N field stop 118 vertically between collector 120 and the emitter 130 may provide WB-BJT 100 with a current gain of about 1 or less. A larger gain may be useful when a BJT is on, but a BJT with large gain may not be robust under breakdown condition. For example, when a BJT with high gain blocks a high voltage, leakage (even without an avalanche breakdown) can cause voltage snap-back and device failure.

A base current from a base electrode 116 on the top or front surface of a vertical device such as WB-BJT 100 may inject (or not) charge carriers into lightly doped base layer 114 to turn on (or turn off) current flow through N− base 114 and N+ field stop 118 between collector electrode 126 on the top surface of WB-BJT 100 and an emitter electrode 132 on a bottom or back surface of WB-BJT 100.

WB-BJT 100 may have an active area containing any desired horizontal plan or layout of base 110 and collector 120. For example, an active area of WB-BJT 100 may include multiple line segments forming base 110 between line-shaped trenches for or regions of collector 120. Alternatively, collector 120 in the active area may form a grid with one or more regions of base 110 being islands surrounded within the grid-shaped collector 120. In another example, base 110 and collector 120 may include a set of concentric circular, square, hexagonal, or other ringed-shaped regions. As described further below, the active area of WB-BJT 100 may be surrounded by edge termination.

WB-BC BJT 100, which may be a semiconductor device integrated on one chip or die as described above, may have its base electrode 116 and collector electrode 126 connected in packaging to a MOSFET chip 150 as schematically shown in FIG. 1B. MOSFET chip 150 may contain a low voltage MOSFET and is in a separate chip or die from WB-BJT 100, and the packaging may connect MOSFET chip 150 to the chip containing WB-BJT 100 to provide a package 190 with the functionality of a power IGBT. For example, MOSFET chip 150 may be rated for voltages less than about 40 V, and the breakdown rating of WB-BJT 100 may be up to 20 KV, in which case MOSFET 150 (and IGBT package 190) may just use a 5V to 15V MOSFET gate voltage up to 20 KV for high voltage switching operations. As shown in FIG. 1B, MOSFET chip 150 may contain an N channel MOSFET when the WB-BJT chip 100 contains a wide-base PNP BJT. Alternatively, MOSFET chip 150 may contain a P channel MOSFET when the WB-BJT chip 100 contains a wide-base NPN BJT.

IGBT package 190 may be connected to switch a positive voltage V as shown in FIG. 1B. In particular, a collector terminal 192 of IGBT package 190 may be positively biased at the voltage V, and emitter terminal 194 of IGBT package 190 may be grounded. Packaging connects emitter electrode 132 of WB-BJT 100, which is a PNP bipolar junction transistor in the example of FIG. 1A, to the collector terminal 192 of IGBT package 190, connects collector electrode 126 to IGBT emitter terminal 194 and to a source terminal 154 of MOSFET chip 150, and connects base electrode 116 of WB-BJT 100 to a drain terminal 152 of MOSFET chip 150. (The IGBT terminal names provided in the example of FIG. 1B are for direct replacement of a high voltage IGBT, therefore the backside of IGBT is designated as collector to connect to the positive high voltage terminal. Similarly, the emitter is the top terminal connected to the negative high voltage terminal, per a conventional industry definition of IGBT terminals, but the terminals of WB-BJT 100, which are named based on structure, are different.) When MOSFET 150 is an NMOS device, applying a positive voltage to a gate terminal 196 of IGBT package 190, which is connected to a gate terminal 106 of MOSFET chip 150, turns on the NMOS device and electrically connects WB-BJT base 110 and collector 120, which grounds base 110 and collector 120. Applying a positive voltage to gate 196 of IGBT package 190 thus causes WB-BJT 100 to conduct a current. IGBT package 190 of FIG. 1B behaves in the same manner as an Insulated Gate Bipolar Transistor (IGBT) as modelled and presented by H. Yilmaz et al. during 1984 IEDM. In principle, the device package of FIG. 1B operates as an IGBT and may provide benefits especially if the Wide Base BJT 100 and the MOSFET 150 as integrated within a package minimize parasitics between the MOSFET 150 and the base connection of WB-BJT 100.

Gate electrode 156 of MOSFET 150 may be shorted to source electrode 154, e.g., by grounding IGBT terminals 194 and 196, to turn off WB-BC BJT 100. In response, drain potential of the MOSFET 150 rises with rising voltage on N base 116, which follows the applied emitter voltage less the built-in junction potential of base-emitter junction in WB-BC BJT 100. This base voltage rise stops when the gap between buried P collectors 122 is completely depleted. Accordingly, the breakdown voltage of MOSFET 150 and the collector-base junction breakdown voltage in WB-BJT 100 should be higher than the pinch off voltage of the lateral lightly doped base gap Wb between the buried P collectors 122.

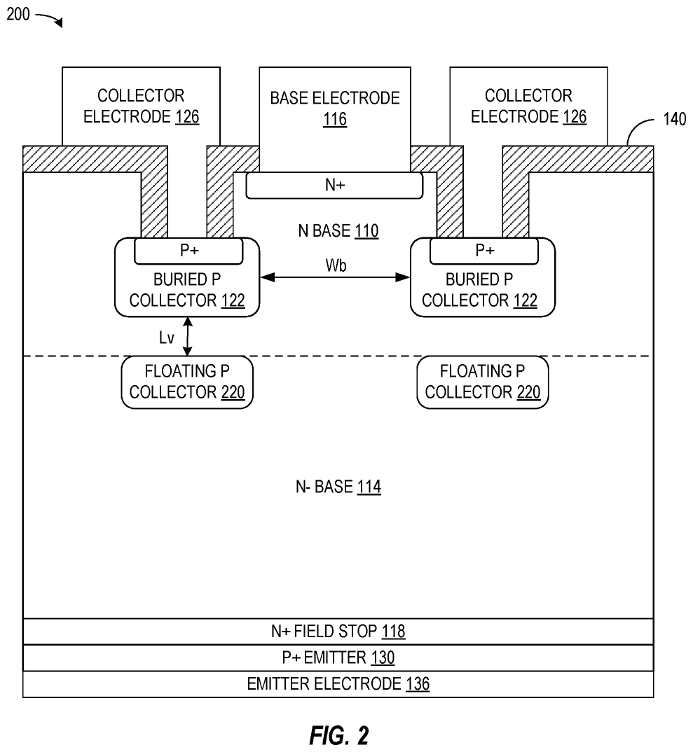

FIG. 2 shows a Wide Base, Buried and Floating Collectors Bipolar Junction Transistor (WB-BFC BJT) 200. FIG. 2 particularly shows an example in which BJT 200 is a PNP Bipolar Junction Transistor and contains many of the same elements described above with reference to FIG. 1. However, to increase charge carrier concentrations in N-type base 110 below and in between boundaries of buried collector 122 in comparison to BJT 100, BJT 200 has floating P collector regions 220 added below and in the vicinity of buried collectors 122. Floating collectors 220 may be buried in N− base layer 114 at a distance Lv below regions of buried collector 122. During the blocking mode of operation of BJT 200, floating collectors 220 follow the collector potential plus a reach through voltage of the gap distance Lv between buried collector 122 and the floating collectors 220. However, during turned on mode of operation of the BJT 200, floating collectors 220 are floating and follow the potential of the surrounding portion of N− base layer 114. As a result, these floating collectors 220 gather both electrons and holes as pairs to reach charge neutrality. In other words, floating collectors 220 store more charge and thus may reduce voltage drop VBE between base electrode 116 and emitter electrode 136. During the turn off, increasing voltage between the collector and emitter separates the stored Electron and Hole Pairs (EHP), and the resulting electric field causes electrons to move towards the emitter and holes to drift towards the buried collectors 120.

Wide Base BJT structures 100 and 200 shown in FIG. 1A and FIG. 2 according to present disclosure can be constructed using various semiconductor materials such as Silicon (Si), Gallium Arsenide (GaAs), Gallium Nitride (GaN), Silicon Carbide (SiC), diamond, or other ternary and quaternary compound semiconductors.

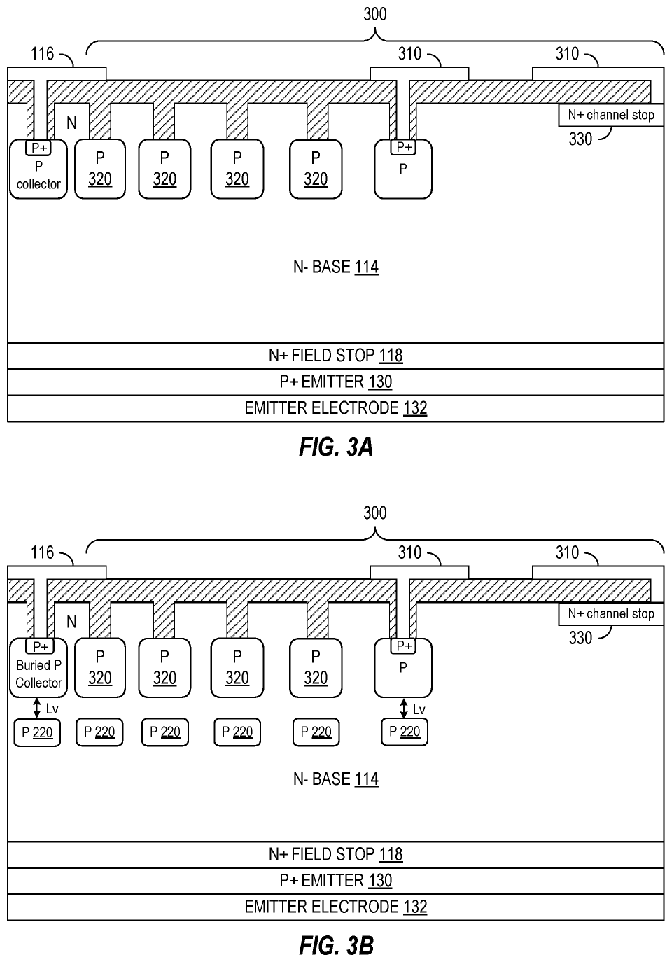

To provide high voltage blocking, an edge termination structure 300 such as shown in FIG. 3A or FIG. 3B may surround the active area of WB-BC BJT 100 or 200 of FIG. 1A or FIG. 2. FIG. 3A shows an example of high voltage edge termination 300 that may be more suitable for WB-BC BJT 100 of FIG. 1A. FIG. 3B shows an example of high voltage edge termination 300 that may be more suitable for WB-BC BJT 100 of FIG. 2. In each example, termination 300 may include floating buried P-type rings 320 that may surround the active area of WB-BC BJT structure 100 or 200 of FIG. 1A or 2. Buried floating P rings 320 may have increasing ring spacing from inner rings toward the die edge and trenches filled with p type polysilicon or dielectric material. Additionally, a field plate 310 and an N+ channel stop 330 may be employed. The buried P rings 320 (and 220 in FIG. 3B) control the electric field in the edge region, so that the active region controls break down. Edge termination structures may further include a field plate 310 and an N+ channel stop 330 that may be used to ensure that depletion does not extend to the cut edge of the die containing WB-BC BJT 100 or 200. The example of edge termination structure 300 shown in FIG. 3B differs from the example shown in FIG. 3A in that FIG. 3B includes floating collectors 220, which are described above with reference to FIG. 2 and may also be used in edge termination structure 300.

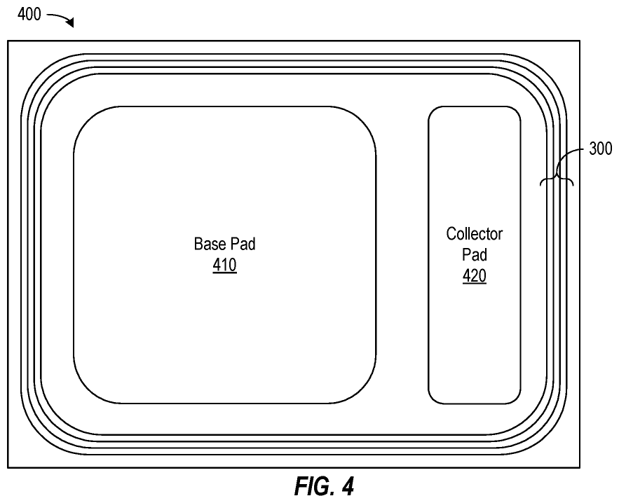

One approach to assemble a MOSFET and a WB-BJT within a package would be to attach a MOSFET chip directly to the metal base electrode of a WB-BJT chip. FIG. 4 shows a conceptual plan view of a BJT chip 400 laid out for packaging. BJT chip 400 may, for example, be integrated circuit chip containing WB-BC BJT 100 or 200. The top or front surface of BJT 400 includes a base pad 410 and a collector pad 420. Base pad 410 may, for example, correspond base electrode 116, which electrically connects to N base 110, and collector pad 420 may correspond to collector electrode 126, which electrically connected to buried collector regions 122. An emitter pad or electrode, e.g., emitter electrode 136, may be on a bottom or back surface of BJT chip 400 and therefore not visible in the view illustrated in FIG. 4.

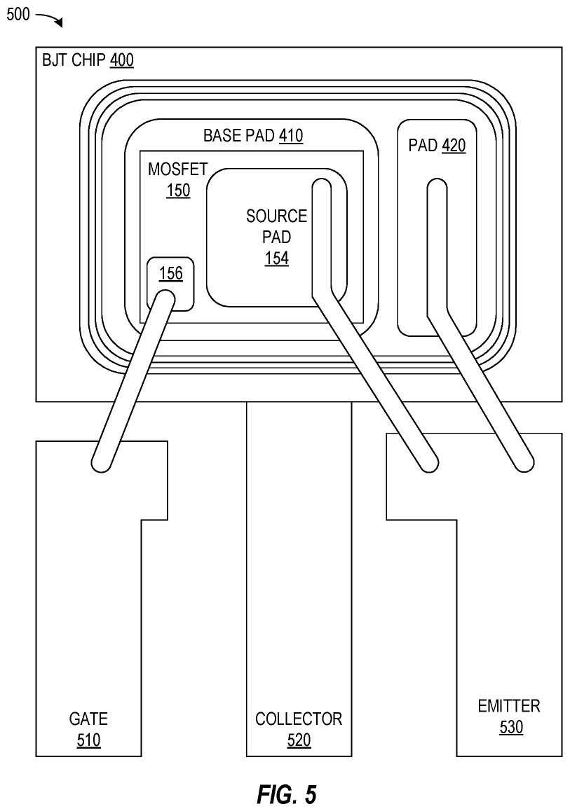

FIG. 5 illustrates the conceptual package integrated MOSFET chip 150 and BJT chip 400 using a package 500, which may be a TO-2XX package such as a TO-220 package. FIG. 5 particularly shows a top view of package 500 before molding encapsulates MOSFET chip 150 and WB BJT chip 400. MOSFET chip 150 may particularly be a vertical MOSFET chip having a gate contact or pad 156 and a source contact or pad 154 on a top surface of MOSFET chip 150 and a drain contact or pad (not visible in FIG. 5) on a bottom surface of MOSFET chip 150. As shown, MOSFET chip 150 may be directly on base pad 410, may reside within the bounds of base pad 410 on BJT chip 400, and may have its bottom drain contact electrically connected to base pad 410 of BJT chip 400. A gate terminal 510 of package 500 may be wire bonded or otherwise connected to gate pad 156 of MOSFET chip 150. A collector terminal 520 of package 500 may be electrically connected to the bottom emitter electrode (not visible in FIG. 5) of BJT chip 400, and an emitter terminal 530 of package 500 may be wire bonded to source pad 154 of MOSFET chip 150 and to collector pad 420 of BJT chip 400.

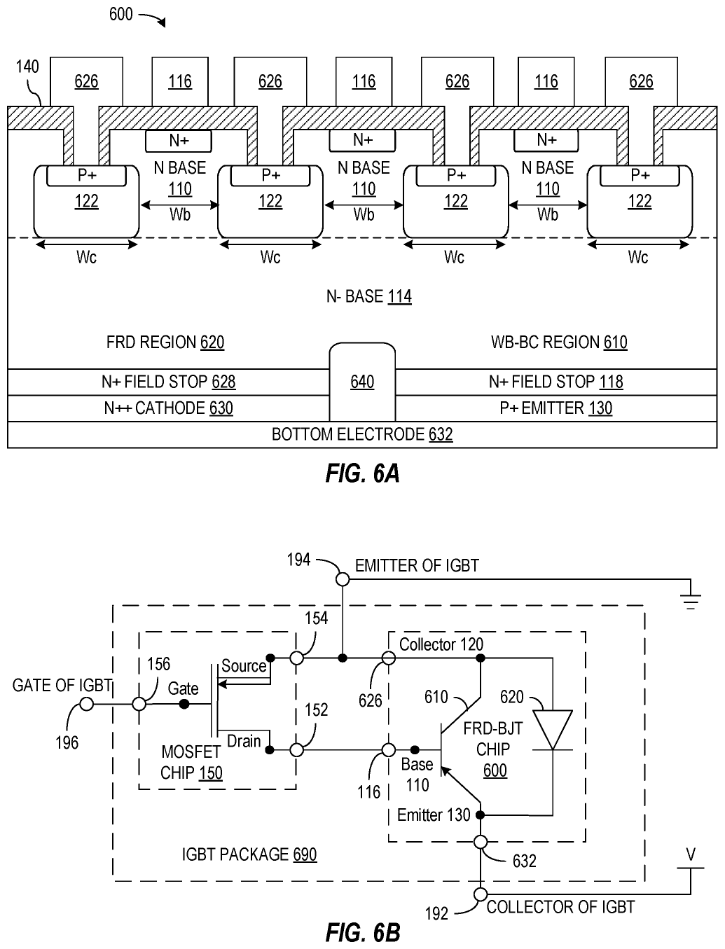

FIG. 6A shows a cross-section of structure 600 that integrates a WB-BC BJT and a Fast Recovery Diode (FRD). In this case, structure 600 includes a WB-BC BJT region 610 and an FRD region 620. WB-BC BJT region 610 includes N-type base 110, buried P-type collector 622, and a P+ emitter region 130 with P+ emitter being adjacent to a bottom electrode 632 as described above. FRD region 620 similarly includes N-type base 110 and buried P-type collector 622 as described above, but in FRD region 620, an N+ cathode region 630 replaces P+ emitter 130 adjacent to the bottom electrode 632. Thus, WB-BC BJT region 610 has a vertical PNP bipolar junction transistor structure, and FRD region 620 has a PN diode structure.

Structure 600 further includes an insulating or semi-insulating region 640 that separates P+ emitter 130 from N++ cathode 630. Region 640 may particularly be a semi-insulating region, rather than an insulating oxide region, for example, when the semiconductor material of structure 600 is Gallium Arsenide (GaAs), Gallium Nitride (GaN), Silicon Carbide (SiC) or another semiconductor material that may be more difficult to oxidize during backside processing that forms region 640 and N++ cathode 630. Region 640 separates N+ field stop/buffer region 118 on P+ emitter 130 from an N+ field stop region 628 on N++ cathode 630 to avoid FRD influence on WB-BC BJT during the turn on operation. Semi-insulating region 640 has resistivity greater than equal 10,000,000 ohm-cm as an industry definition and can be formed, for example, by proton implantation from a wafer backside after backside grinding and etching. Semi-insulating region 640 minimizes electrons going to cathode 630 of the FRD region 620 at the interface of P+ emitter 130 and N++ cathode 630. Increased lateral resistance in the semi-insulating region reduces electron diversion from the collector towards the N++ cathode 630 in the vicinity of the interface between P+ emitter 130 and N++ cathode 630. Without the semi-insulting region, WB-BC BJT may have higher Vce initially and then at higher currents, Vce will be reduced by N− base modulation due to electrons and holes storage in the base, which will cause a negative resistance effect during IGBT operation after integrating WB-BC BJT with a MOSFET inside a package.

FIG. 6B shows the circuit equivalent of the integrated FRD and WB-BC BJT structure 600 of FIG. 6A and package connections to a MOSFET chip 150 in an IGBT package 690. IGBT package 690 has terminals 192, 194, and 196 for operation as the equivalent of an IGBT, but WB-BJT chip 600 includes not only a WB-BJT 610 but also a FRD 620. A fast recovery diode as provided in IGBT package 690 may be required or have advantages, particularly when IGBT package 690 may be employed for switching power provided to an inductive load.

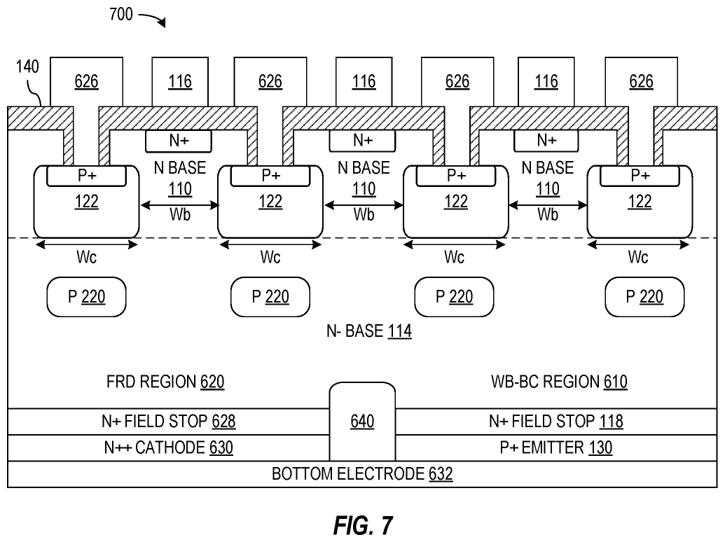

FIG. 7 shows a structure 700 of a WB-BC PNP BJT including floating P regions 220 with an integrated FRD. FRD and WB-BC BJT structure 700 may include the same elements as described above with reference to FIG. 6A and may be used in a package such as illustrated in FIG. 6B. Structure 700, however, further includes floating P collector regions 220, which are described above with reference to FIG. 2. As described above, floating P collector regions 220 may increase charge carrier concentrations in N-type base 110 below and in between boundaries of buried collector 122 in comparison to BJT 100.

Although particular implementations have been disclosed, these implementations are only examples and should not be taken as limitations. Various adaptations and combinations of features of the implementations disclosed are within the scope of the following claims.

What is claimed is:

1. A vertical Bipolar Junction Transistor (BJT) device comprising:
a first layer of a semiconductor having a first conductivity type, the first layer forming an emitter;
a second layer of a semiconductor having a second conductivity type, the second layer including containing a drift region and a field stop region on the first layer; and
one or more collector regions of the first conductivity type in the second layer, the collector regions having boundaries laterally separated by a separation Wb forming one or more base regions between the boundaries of the collector regions.

2. The vertical BJT device of claim 1, wherein the collector regions are connected to a collector electrode and the base regions are connected to a base electrode.

3. The vertical BJT device of claim 1, wherein the collector electrode and the base electrode are on a top surface of the vertical BJT device, and the vertical BJT device further comprises an emitter electrode on a bottom surface of the BJT device and contacting the first layer.

4. The vertical BJT device of claim 1, wherein the first conductivity type is P-type, and the second conductivity type is N-type.

5. The vertical BJT device of claim 1, wherein the collector regions are regions of the first conductivity type buried into a portion of the second layer that is lightly doped with dopants of the second conductivity type, and the base regions extend above the collector regions.

6. The vertical BJT device of claim 4, wherein the collector regions are at the bottom of trenches and the base regions extend between the trenches.

7. The vertical BJT device of claim 1, further comprising one or more floating regions of the first conductivity type that are separated vertically from and below the collector regions.

8. The vertical BJT device of claim 1, wherein the first layer is the emitter in a first area of the vertical BJT chip, the vertical BJT device further comprising:
a diode region of the second conductivity type in the first layer in a second area of the vertical BJT device;
a semi-insulating region separating the diode region of the second conductivity type from the first layer of the first conductivity type; and
a bottom electrode contacting the diode region of the second conductivity type and the first layer of the first conductivity type, wherein:
the emitter, the collector regions, and the base regions form a BJT in the first area; and
the collector regions, the second layer, and the diode region form a diode in the second area.

9. A vertical Bipolar Junction Transistor (BJT) comprising:
a first layer of a semiconductor having a first conductivity type semiconductor and forming an emitter of the vertical BJT;
a second layer of a semiconductor having a second conductivity type and forming a drift region and a field stop region for voltage blocking, the second layer including one or more trenches;
one or more collector regions of the first conductivity type at a bottom of the trenches, the collector regions having boundaries laterally separated by a gap Wb;
conductive material connecting the collector regions at the bottom of the trenches via trenches to a collector electrode;
one or more base regions of the second conductivity type and overlying the drift region, the base regions being more heavily doped than the drift region and being connect to the drift region through the gap Wb; and
a base electrode connected to the base regions.

10. The vertical BJT of claim 9, further comprising an active transistor area and a high voltage edge termination area, the termination area containing buried floating p rings with increasing ring spacing from inner rings toward a die edge and trenches filled with polysilicon or dielectric material.

11. A vertical Bipolar Junction Transistor (BJT) comprising:
a first layer of a first conductivity type semiconductor forming an emitter;
a second layer of a second conductivity type semiconductor containing a drift region and a field stop region, the second layer further containing:
one or more trenches on top of one or more buried collector regions of the first conductivity type;
the buried collector regions having boundaries separated laterally by a gap Wb; and
one or more floating regions of the first conductivity type that are separated vertically from and below the buried collector regions;
conductive material connecting the buried collector regions at the bottom of the trenches via the trenches to a collector electrode; and
one or more base regions of the second conductivity type connected to a base electrode, the base regions being between the trenches.

12. The vertical BJT of claim 11, further comprising an active transistor area and an edge termination area, the edge termination area containing:
a plurality of first floating rings just below trenches that are filled with polysilicon or dielectric material, wherein the first floating rings have the first conductivity type, surround the active transistor area, and have increasing ring spacing toward a die edge; and
a plurality of second floating rings within the second layer below the first floating rings.

13. A hybrid Insulated Gate Bipolar Transistor (IGBT), comprising:
a bipolar junction transistor (BJT) chip;
a vertical MOSFET chip on top of a base electrode of the BJT chip, a drain terminal of the vertical MOSFET chip being electrically connected the base electrode;
a first package terminal electrically connected to a collector electrode of the BJT chip;
a second package terminal electrically connected to a source electrode of the vertical MOSFET chip and electrically connected to a collector electrode of the BJT chip; and
a third package terminal connected to a gate electrode of the vertical MOSFET chip.

14. The hybrid IGBT of claim 13, wherein the BJT chip comprises one or more buried collector regions having boundaries defining a gap through which an emitter region of the BJT chip connects to an underlying drift region of the BJT chip.

15. The hybrid IGBT of claim 14, wherein the BJT chip further comprises one or more floating collectors below the buried collector regions.

16. The hybrid IGBT of claim 13, wherein the BJT chip further comprises a Fast Recovery Diode (FRD).

17. The hybrid IGBT of claim 13, wherein the BJT chip comprises a wide-base PNP BJT, the vertical MOSFET chip comprises an N channel MOSFET, and the hybrid IGBT forms N-channel hybrid IGBT.

18. The hybrid IGBT of claim 13, wherein the BJT chip comprises a wide-base NPN BJT, the vertical MOSFET chip comprises a P channel MOSFET, and the hybrid IGBT forms P-channel hybrid IGBT.
